(19) United States
(12) Patent Application Publication
(10) Pub. No.: US 2025/0323471 A1
(43) Pub. Date: Oct. 16, 2025

(54) TUNABLE NARROW SPECTRAL WIDTH HIGH POWER SEMICONDUCTOR LASER SYSTEM

(71) Applicant: Turning Point Lasers Corporation, Hsinchu City (TW)

(72) Inventors: Hsiao Hua WU, Hsinchu City (TW); Li Chang Tsou, Hsinchu City (TW); Tzu Neng LIN, Hsinchu County (TW); Chi Luen Wang, Hsinchu City (TW); Hung Sheng Lee, Taipei City (TW); Tai Ming Chang, New Taipei City (TW); Szutsun Simon Ou, Taipei City (TW)

(73) Assignee: Turning Point Lasers Corporation, Hsinchu City (TW)

(21) Appl. No.: 19/095,984

(22) Filed: Mar. 31, 2025

(30) Foreign Application Priority Data
Apr. 10, 2024 (TW) 113113223

(51) Int. Cl. H01S 5/40; H01S 5/00

(52) U.S. Cl. CPC H01S 5/4012; H01S 5/005

(57) ABSTRACT

A semiconductor laser system is used for generating wavelength tunable and narrow spectral width high power laser beam. The system includes but not limited to a semiconductor laser module and an optical system. The module consists of N laser diodes, each equipped with a fast-axis collimator, slow-axis collimator, and reflective mirror, at different height, such that on the output plane the laser beams stacked along fast-axis of the diode laser. The optical system is employed to feed a fraction of the beams with selected wavelength and spectral width back into each laser diode, which comprises a pair of cylindrical lenses, a half wave plate, a transmission grating, and an output coupler mirror.

### BACKGROUND OF THE INVENTION

### 1. Field of the Invention

The invention relates to a tunable narrow spectral width high power semiconductor laser system, especially to one can adjust the wavelength and obtain a narrow spectral width.

### 2. Description of the Related Art

Current tunable narrow spectral width high power semiconductor laser system typically uses a single laser diode and adopt an external resonant cavity architecture with a dispersive element. The output power of this type of system is usually low, which is not conducive to high-power applications. Narrow spectral width high power semiconductor laser system can use spatial beam combining of a stack of semiconductor lasers, and adopt an external resonant cavity architecture with a volumetric holographic grating. In this system, the wavelength and the grating temperature shift slightly with the laser operating power but cannot be adjusted over a wide range.

### SUMMARY OF THE INVENTION

It is a primary objective of the present invention to achieve a tunable narrow spectral width high power semiconductor laser system.

In order to achieve the above objectives, the present includes: a semiconductor laser module, the semiconductor laser module has N laser diodes, each laser diodes is equipped with a fast-axis collimator, a slow-axis collimator and a reflective mirror at different height, so that N laser beams stacked along fast-axis of the diode laser on the output plane; an optical system, composed of a first cylindrical lens, a second cylindrical lens, a half wave plate, a transmission grating and an output coupler mirror; the laser beam passes through the first cylindrical lens and the second cylindrical lens in the optical system in sequence, expands in the slow axis direction to a beam with a larger cross-sectional area and a smaller divergence angle, then passes through the half wave plate to change the polarization direction, and passes through the transmission grating at an incident angle, rotating the half wave plate to change the polarization direction and adjusting the transmission grating to change the incident angle to obtain the maximum first-order diffraction efficiency of the transmitted light, the transmitted light is vertically incident on the output coupler mirror, and a light beam with R1 times incident power is reflected back to each laser diodes in the semiconductor laser module along the original path.

In a preferred embodiment, the first cylindrical lens is close to the semiconductor laser module and has a focal length of f1; the second cylindrical lens is close to the transmission grating and has a focal length of f2; wherein f1 is positive or negative, f2 is positive, and f1 is smaller than f2.

In a preferred embodiment, further includes two semiconductor laser modules and two optical systems, which are symmetrically arranged and share the same transmission grating, while narrowing the spectral width of the two semiconductor laser modules and independently adjusting the wavelengths of the two semiconductor laser modules.

In a preferred embodiment, the present invention comprising: a semiconductor laser module, the semiconductor laser module has N laser diodes, each laser diodes is equipped with a fast-axis collimator, a slow-axis collimator and a reflective mirror at different height, so that N laser beams stacked along fast-axis of the diode laser on the output plane. an optical system, composed of a first cylindrical lens, a second cylindrical lens, a half wave plate, a transmission grating and an output coupler mirror; the laser beam passes through the half wave plate to change the polarization direction, and passes through the transmission grating at an incident angle, rotating the half wave plate to change the polarization direction and adjusting the transmission grating to change the incident angle to obtain the maximum first-order diffraction efficiency of the transmitted light, the transmitted light passes through the first cylindrical lens and the second cylindrical lens in the optical system in sequence, condensed in the slow axis direction to a beam with a smaller cross-sectional area and a larger divergence angle, then the transmitted light is vertically incident on the output coupler mirror, and a light beam with R1 times incident power is reflected back to each laser diodes in the semiconductor laser module along the original path.

Also, the first cylindrical lens is close to the transmission grating and has a focal length of f1; the second cylindrical lens is close to the output coupler mirror and has a focal length of f2; wherein f1 is positive, f2 is positive or negative, and f1 is larger than f2.

Also, further includes two semiconductor laser modules and two optical systems, which are symmetrically arranged and share the same transmission grating, while narrowing the spectral width of the two semiconductor laser modules and independently adjusting the wavelengths of the two semiconductor laser modules.

Also, one of the first and second cylindrical lenses is placed on a translation stage to adjust the distance between the first and second cylindrical lenses to f1+f2 to narrow the spectral width of the laser spectrum. Also, further includes adjusting the tilt angle of the output coupler mirror and observing the output spectrum of the laser system, thereby suppressing the side mode and obtaining a narrow spectral width laser spectrum through optimal light feedback.

Also, further includes adjusting the azimuth angle of the output coupler mirror and observing the output spectrum of the laser system to change the wavelength of the laser light.

### BRIEF DESCRIPTION OF THE DRAWINGS

FIG. 1A is a schematic diagram illustrating the structure of the semiconductor laser module of the present invention;

FIG. 1B is a side view of the laser diodes of the semiconductor laser module of the present invention;

FIG. 1C is a top view of the semiconductor laser module of the present invention;

FIG. 1D is a schematic diagram illustrating intensity distribution of the semiconductor laser module and N laser beams stacked along fast-axis of the present invention;

FIG. 2 is a schematic diagram illustrating the first embodiment of the present invention, the system includes a semiconductor laser module and an optical system, one pair of cylindrical lenses is placed between the laser module and the transmission grating;

FIG. 3 is a schematic diagram illustrating the second embodiment of the present invention, the system includes a semiconductor laser module and an optical system, one pair of cylindrical lenses is placed between the output coupler mirror and the transmission grating;

FIG. 4 is a laser spectrum of the present invention when there is no optical feedback;

FIG. 5 is a laser spectrum of the present invention when having optimal optical feedback;

FIG. 6 is a laser spectrum of the present invention showing the change in wavelength of laser light by adjusting the azimuth angle of the output coupler mirror.

FIG. 7 is a schematic diagram illustrating the third embodiment of the present invention, which is derived from the first embodiment, one of the transmission gratings is used to narrow the spectral width of two semiconductor laser modules, and the wavelengths of the two semiconductor laser modules can be adjusted independently by their output coupler mirrors;

FIG. 8 is a schematic diagram illustrating the third embodiment of the present invention, which is derived from the fourth embodiment, one of the transmission gratings is used to narrow the spectral width of two semiconductor laser modules, and the wavelengths of the two semiconductor laser modules can be adjusted independently by their output coupler mirrors.

### DETAILED DESCRIPTION OF THE PREFERRED EMBODIMENT

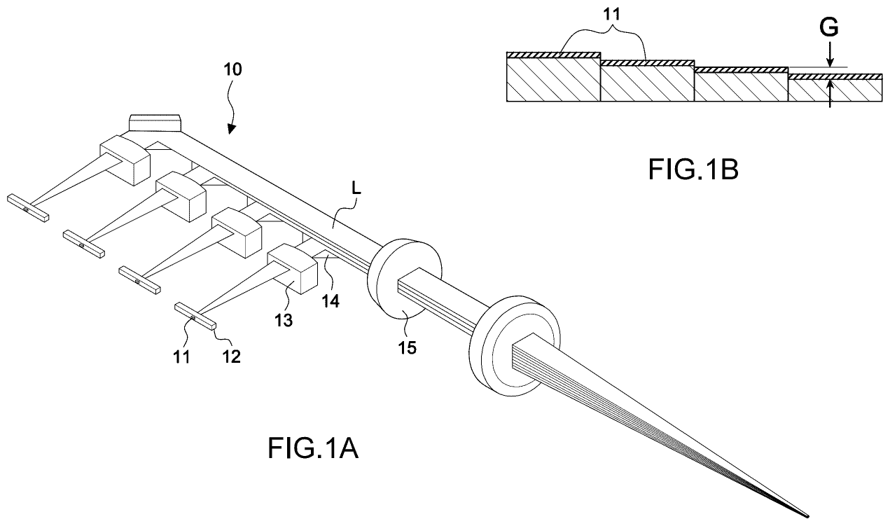

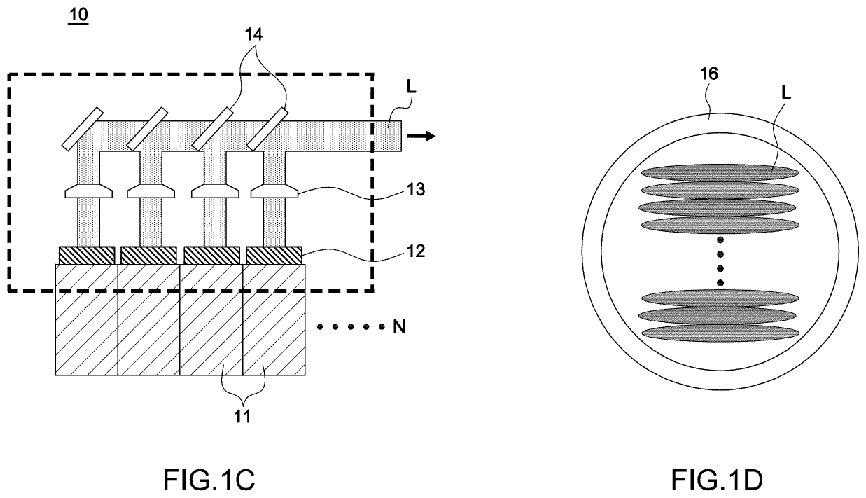

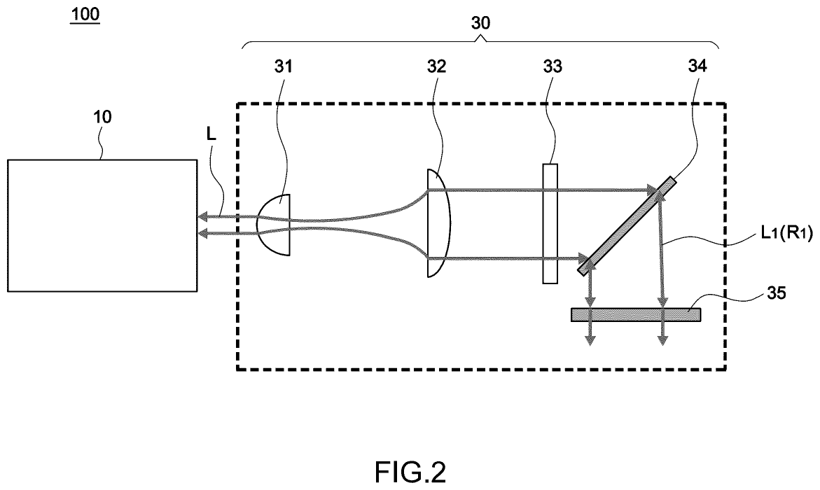

First, referring to FIG. 1A-8, which shows the preferred embodiments of a tunable narrow spectral width high power semiconductor laser system. FIG. 2 shows the first embodiment 100 of the present invention, the first embodiment 100 of the present invention includes: a semiconductor laser module 10, the semiconductor laser module 10 has N laser diodes 11, each laser diodes 11 is equipped with a fast-axis collimator 12, a slow-axis collimator 13, a reflective mirror 14 and a focusing lens 15 to couple the laser beam L out. Each laser diodes 11 is arranged at different height, as FIG. 1B showing, so that N laser beams L stacked along fast-axis of the diode laser 11 on the output plane 16, as FIG. 1D showing.

In the first embodiment 100 of the present invention, the semiconductor laser module 10 has N laser diodes 11, the light emitting area (infrared light) of each laser diodes 11 is approximately 1 micron high and 100 microns wide (approximately 15 watts), 150 microns (20 watts), or 230 microns (30 watts), and (blue light) is approximately 1 micron high and 45 microns wide (˜5 watts). Due to the diffraction effect, the divergence angle of the laser diodes is about 26°˜30° in the vertical (fast axis) direction and about 5°˜7° in the horizontal direction. Therefore, a fast axis collimator 12 is provided near the output of each laser diodes 11 to correct the divergence angle in the vertical direction into approximately parallel collimated light; then, the slow axis collimator 13 is provided to correct the divergence angle in the horizontal direction to be approximately parallel collimated light, and a reflecting mirror 14 is also provided. Each laser diodes 11 is arranged at different height, as FIG. 1B showing, so that N laser beams L stacked along fast-axis of the diode laser 11 on the output plane 16, as FIG. 1D showing. The features of the semiconductor laser module 10 have been disclosed in my own prior art, so will not be mentioned in detail.

Referring to FIG. 2, in the first embodiment 100 of the present invention includes: an optical system 30, composed of a first cylindrical lens 31, a second cylindrical lens 32, a transmission grating 34 and an output coupler mirror 35; the laser beam L passes through the first cylindrical lens 31 with the focal length f1 and the second cylindrical lens 32 with the focal length f2 in the optical system 30 in sequence, expands in the slow axis direction to a beam with a larger cross-sectional area and a smaller divergence angle, then passes through a half wave plate 33 to change the polarization direction, and passes through the transmission grating 34 at an incident angle θ1, rotating the half wave plate 33 to change the polarization direction and adjusting the transmission grating 34 to change the incident angle to obtain the maximum first-order diffraction efficiency of the transmitted light L1, the transmitted light L1 is vertically incident on the output coupler mirror 35, and a light beam with R1 times incident power is reflected back to each laser diodes 11 in the semiconductor laser module 10 along the original path.

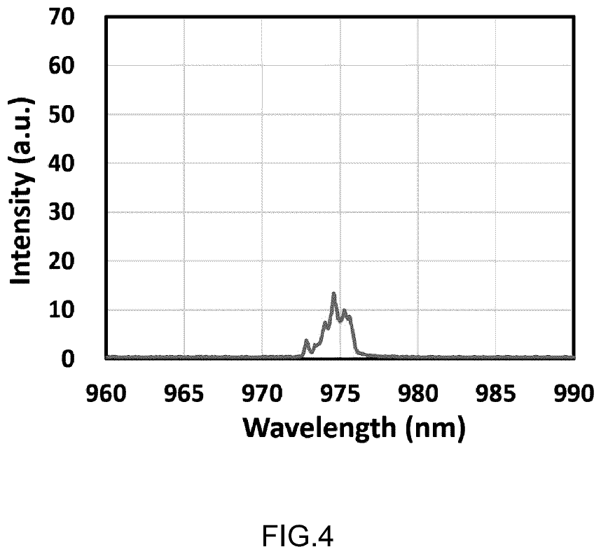

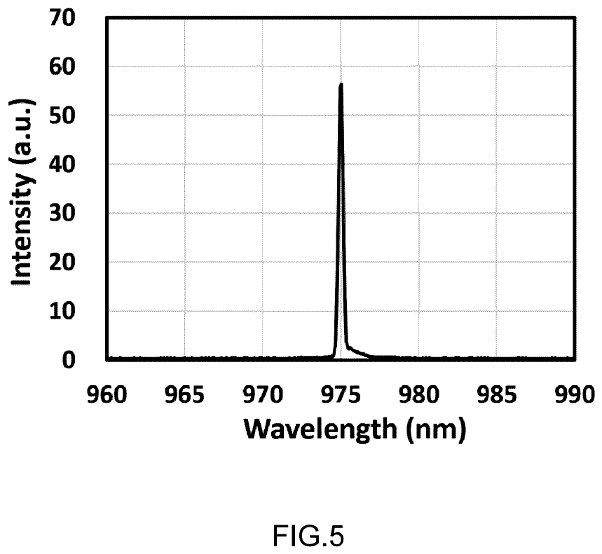

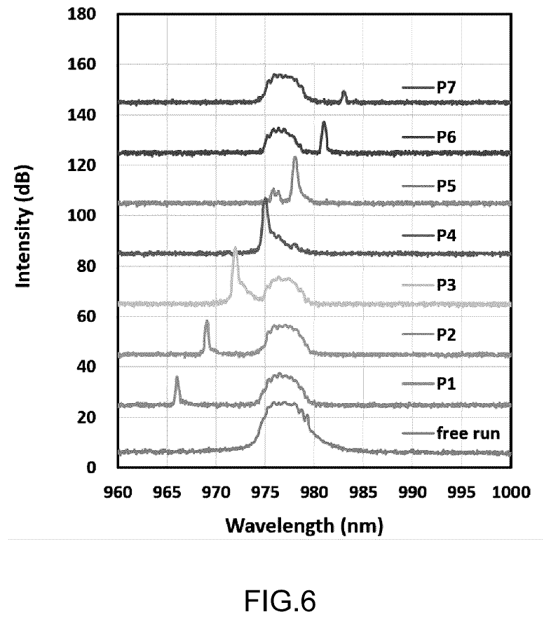

Therefore, in the first embodiment 100, a pair of first cylindrical lens 31 and second cylindrical lens 32 are placed between the semiconductor laser module 10 and the transmission grating 34. The cylindrical lenses are arranged in such a way that they form a beam expansion system in the slow axis direction. The first cylindrical lens 31 is close to the semiconductor laser module 10 and has a focal length of f1; the second cylindrical lens 32 is close to the transmission grating 34 and has a focal length of f2; wherein f1 is positive or negative, f2 is positive, and f1 is smaller than f2. One of the first 31 and second cylindrical lenses 32 is placed on a translation stage to adjust the distance between the first and second cylindrical lenses to f1+f2 to narrow the spectral width of the laser spectrum. Adjust the distance between the first and second cylindrical lenses to f1+f2 and make f1 smaller than f2, at this time, the two cylindrical lenses form a beam expansion system in the slow axis direction. Fine-tuning this distance can change the light shape fed back to each laser diodes to achieve the best beam spectral width narrowing effect. In addition, adjusting the tilt angle of the output coupler mirror 35 to make the feedback beam and the gain region of each single laser diodes achieve best overlap, which is also a necessary condition for achieving spectral width narrowing. The laser spectrum with no light feedback and with the best light feedback are shown in FIG. 4 and FIG. 5 respectively. The change of wavelength can be achieved by adjusting the azimuth angle of the output coupler mirror 35, when the azimuth angle of the output coupler mirror 35 is adjusted, the spectrum diagram of the change of the wavelength of the laser light is shown in FIG. 6. Therefore, the present invention adjusts the tilt angle of the output coupler mirror 35 and observing the output spectrum of the laser system, thereby suppressing the side mode and obtaining a narrow spectral width laser spectrum through optimal light feedback, and the present invention adjusts the azimuth angle of the output coupler mirror 35 and observing the output spectrum of the laser system to change the wavelength of the laser light.

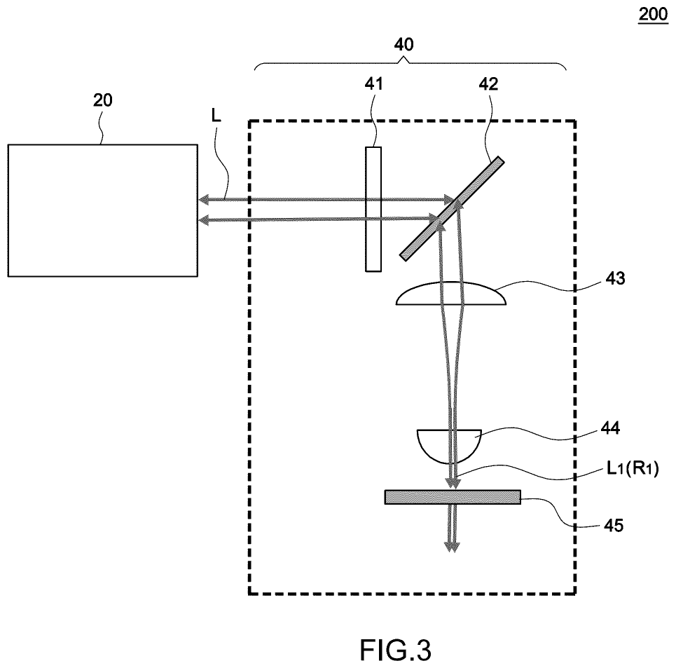

Referring to FIG. 3, which shows the second embodiment 200 of the present invention. In the second embodiment 200, the feature of the semiconductor laser module 20 is the same as the semiconductor laser module 10 of the first embodiment 100, so will not be mentioned in detail. An optical system 40, composed of a half wave plate 41, a first cylindrical lens 43, a second cylindrical lens 44, a transmission grating 42 and an output coupler mirror 45; The difference between the second embodiment 200 and the first embodiment 100 is: the laser beam L first passes through a half wave plate 41 to change the polarization direction, and passes through the transmission grating 42 at an incident angle θ1, rotating the half wave plate 41 to change the polarization direction and adjusting the transmission grating 42 to change the incident angle to obtain the maximum first-order diffraction efficiency of the transmitted light L1, the transmitted light L1 passes through the first cylindrical lens 43 with the focal length f1 and the second cylindrical lens 44 with the focal length f2 in sequence, condensed in the slow axis direction to a beam with a smaller cross-sectional area and a larger divergence angle, the transmitted light L1 is vertically incident on the output coupler mirror 45, and a light beam with R1 times incident power is reflected back to each laser diodes in the semiconductor laser module 20 along the original path.

Therefore, in the second embodiment 200, a pair of first cylindrical lens 43 and second cylindrical lens 44 are placed between the transmission grating 42 and output coupler mirror 45. The cylindrical lenses are arranged in such a way that they form a beam expansion system in the slow axis direction. The first cylindrical lens 43 is close to the transmission grating 42 and has a focal length of f1; the second cylindrical lens 44 is close to the output coupler mirror 45 and has a focal length of f2; wherein f1 is positive, f2 is positive or negative, and f1 is larger than f2. Adjust the distance between first 43 and second cylindrical lenses 44 to f1+f2 and make f1 larger than f2, at this time, the two cylindrical lenses form a beam reduction system in the slow axis direction. Fine-tuning this distance can change the light shape fed back to each laser diodes to achieve the best beam spectral width narrowing effect. In addition, adjusting the tilt angle of the output coupler mirror 45 to make the feedback beam and the gain region of each single laser diodes achieve the best overlap, which is also a necessary condition for achieving spectral width narrowing. The laser spectrum with no light feedback and with the best light feedback are shown in FIG. 4 and FIG. 5 respectively. The change of wavelength can be achieved by adjusting the azimuth angle of the output coupler mirror 45, when the azimuth angle of the output coupler mirror 45 is adjusted, the spectrum diagram of the change of the wavelength of the laser light is shown in FIG. 6. Therefore, the present invention adjusts the tilt angle of the output coupler mirror 35 and observing the output spectrum of the laser system, thereby suppressing the side mode and obtaining a narrow spectral width laser spectrum through optimal light feedback, and the present invention adjusts the azimuth angle of the output coupler mirror 35 and observing the output spectrum of the laser system to change the wavelength of the laser light.

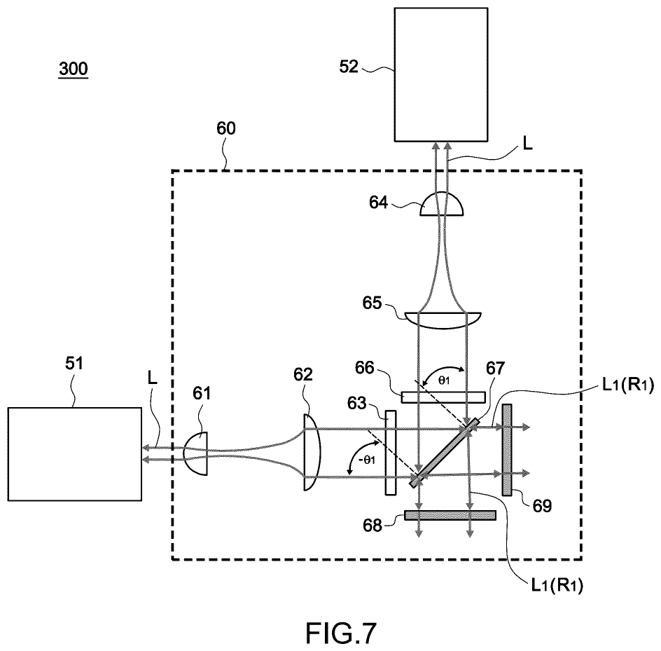

FIG. 7 is a schematic diagram of the system architecture of a third embodiment 300 of the tunable narrow spectral width high power semiconductor laser system of the present invention, which is derived from the first embodiment 100. It can be extended to use a transmission grating 42 to adjust and narrow the wavelength and spectral width of the two laser modules. The light beam from one semiconductor laser module enters the transmission grating at θ1, and the light beam from the other semiconductor laser module enters the transmission grating at −θ1.

The third embodiment 300 includes two semiconductor laser modules 51, 52 and two optical systems, which are symmetrically arranged and share the same transmission grating 67, narrowing the spectral width of the two semiconductor laser modules and independently adjusting the wavelength of the two semiconductor laser modules. Wherein the laser beam L generated by a first laser module 51 passes through the first cylindrical lens 61 with the focal length f1 and the second cylindrical lens 62 with the focal length f2 in the optical system 60 in sequence, expands in the slow axis direction to a beam with a larger cross-sectional area and a smaller divergence angle, then passes through a half wave plate 63 to change the polarization direction, and passes through the transmission grating 67 at an incident angle θ1, rotating the half wave plate 63 to change the polarization direction and adjusting the transmission grating 67 to change the incident angle to obtain the maximum first-order diffraction efficiency of the transmitted light L1, the transmitted light L1 is vertically incident on the output coupler mirror 68, and a light beam with R1 times incident power is reflected back to each laser diodes in the semiconductor laser module 51 along the original path.

In the third embodiment 300, adjust the distance between first 61 and second cylindrical lenses 62 to f1+f2 and make f1 smaller than f2, at this time, the two cylindrical lenses form a beam expansion system in the slow axis direction. Fine-tuning this distance can change the light shape fed back to each laser diodes to achieve the best beam spectral width narrowing effect. In addition, adjusting the tilt angle of the output coupler mirror 68 to make the feedback beam and the gain region of each single laser diodes achieve best overlap, which is also a necessary condition for achieving spectral width narrowing. The change of wavelength can be achieved by adjusting the azimuth angle of the output coupler mirror 68.

In the third embodiment 300, wherein the laser beam L1 generated by a first laser module 52 passes through the first cylindrical lens 64 with the focal length f1 and the second cylindrical lens 65 with the focal length f2 in the optical system 60 in sequence, expands in the slow axis direction to a beam with a larger cross-sectional area and a smaller divergence angle, then passes through a half wave plate 66 to change the polarization direction, and passes through the transmission grating 67 at an incident angle θ1, rotating the half wave plate 66 to change the polarization direction and adjusting the transmission grating 67 to change the incident angle to obtain the maximum first-order diffraction efficiency of the transmitted light L1, the transmitted light L1 is vertically incident on the output coupler mirror 69, and a light beam with R1 times incident power is reflected back to each laser diodes in the semiconductor laser module 52 along the original path. Adjust the distance between first 64 and second cylindrical lenses 65 to f1+f2 and make f1 smaller than f2, at this time, the two cylindrical lenses form a beam expansion system in the slow axis direction. Fine-tuning this distance can change the light shape fed back to each laser diodes to achieve the best beam spectral width narrowing effect. In addition, adjusting the tilt angle of the output coupler mirror 69 to make the feedback beam and the gain region of each single laser diodes achieve the best overlap, which is also a necessary condition for achieving spectral width narrowing. The change of wavelength can be achieved by adjusting the azimuth angle of the output coupler mirror 69. This derivative system uses a single grating to narrow the spectral width of two laser modules simultaneously, and can independently adjust the wavelengths of the two laser modules.

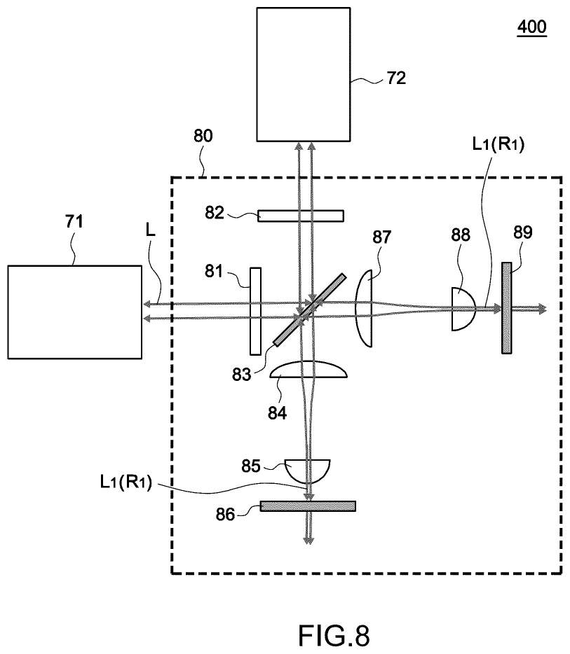

FIG. 8 is a schematic diagram of the system architecture of the fourth embodiment 400 of the tunable narrow spectral width high power semiconductor laser system of the present invention, which is derived from the second embodiment 200 and can be extended to use a transmission grating to adjust and narrow the wavelength and spectral width of two laser modules. The embodiment comprises two semiconductor laser modules and two optical systems, which are symmetrically arranged and share the same transmission grating, narrowing the spectral width of the two semiconductor laser modules at the same time, and independently adjusting the wavelength of the two semiconductor laser modules. The light beam from one semiconductor laser module enters the transmission grating at θ1, and the light beam from the other semiconductor laser module enters the transmission grating at −θ1.

In the fourth embodiment 400, the laser beam generated by a first laser module 71 passes through the half wave plate 81 in the optical system 80 to change the polarization direction, and passes through the transmission grating 83 at an incident angle θ1, rotating the half wave plate 81 to change the polarization direction and adjusting the transmission grating 83 to change the incident angle to obtain the maximum first-order diffraction efficiency of the transmitted light L1; the transmitted light L1 passes through the first cylindrical lens 84 with the focal length f1 and the second cylindrical lens 85 with the focal length f2, condensed in the slow axis direction to a beam with a smaller cross-sectional area and a larger divergence angle, then the transmitted light L1 is vertically incident on the output coupler mirror 86, and a light beam with R1 times incident power is reflected back to each laser diodes in the semiconductor laser module 71 along the original path. Adjust the distance between first 84 and second cylindrical lenses 85 to f1+f2 and make f1 larger than f2, at this time, the two cylindrical lenses form a beam reduction system in the slow axis direction. Fine-tuning this distance can change the light shape fed back to each laser diodes to achieve the best beam spectral width narrowing effect. In addition, adjusting the tilt angle of the output coupler mirror 86 to make the feedback beam and the gain region of each single laser diodes achieve best overlap, which is also a necessary condition for achieving spectral width narrowing. The change of wavelength can be achieved by adjusting the azimuth angle of the output coupler mirror 86.

In the fourth embodiment 400, the laser beam generated by a second laser module 72 passes through the half wave plate 82 in the optical system 80 to change the polarization direction, and passes through the transmission grating 83 at an incident angle θ1, rotating the half wave plate 82 to change the polarization direction and adjusting the transmission grating 83 to change the incident angle to obtain the maximum first-order diffraction efficiency of the transmitted light L1; the transmitted light L1 passes through the first cylindrical lens 87 with the focal length f1 and the second cylindrical lens 88 with the focal length f2, condensed in the slow axis direction to a beam with a smaller cross-sectional area and a larger divergence angle, then the transmitted light L1 is vertically incident on the output coupler mirror 89, and a light beam with R1 times incident power is reflected back to each laser diodes in the semiconductor laser module 72 along the original path. Adjust the distance between first 87 and second cylindrical lenses 88 to f1+f2 and make f1 larger than f2, at this time, the two cylindrical lenses form a beam reduction system in the slow axis direction. Fine-tuning this distance can change the light shape fed back to each laser diodes to achieve the best beam spectral width narrowing effect. In addition, adjusting the tilt angle of the output coupler mirror 89 to make the feedback beam and the gain region of each single laser diodes achieve the best overlap, which is also a necessary condition for achieving spectral width narrowing. The change of wavelength can be achieved by adjusting the azimuth angle of the output coupler mirror 89. This derivative system uses a single grating to narrow the spectral width of two laser modules simultaneously, and can independently adjust the wavelengths of the two laser modules.

Therefore, the present invention with the technical features of the first to fourth embodiments mentioned above, by adjusting the “tilt angle” of the output coupler mirror, while observing the output spectrum of the laser system, to suppress the side mode through optimal light feedback and obtain a laser spectrum with a narrow spectral width; and adjusts the “azimuth angle” of the output coupler mirror while observing the output spectrum of the laser system to change the wavelength of the laser light.

Although particular embodiments of the invention have been described in detail for purposes of illustration, various modifications and enhancements may be made without departing from the spirit and scope of the invention. Accordingly, the invention is not limited except as by the appended claims.

What is claimed is:

1. A tunable narrow spectral width high power semiconductor laser system, comprising:
a semiconductor laser module, the semiconductor laser module has N laser diodes, each laser diodes is equipped with a fast-axis collimator, a slow-axis collimator and a reflective mirror at different height, so that N laser beams stacked along fast-axis of the diode laser on the output plane;
an optical system, composed of a first cylindrical lens, a second cylindrical lens, a half wave plate, a transmission grating and an output coupler mirror; the laser beam passes through the first cylindrical lens and the second cylindrical lens in the optical system in sequence, expands in the slow axis direction to a beam with a larger cross-sectional area and a smaller divergence angle, then passes through the half wave plate to change the polarization direction, and passes through the transmission grating at an incident angle, rotating the half wave plate to change the polarization direction and adjusting the transmission grating to change the incident angle to obtain the maximum first-order diffraction efficiency of the transmitted light, the transmitted light is vertically incident on the output coupler mirror, and a light beam with R1 times incident power is reflected back to each laser diodes in the semiconductor laser module along the original path; and
the first cylindrical lens is close to the semiconductor laser module and has a focal length of f1; the second cylindrical lens is close to the transmission grating and has a focal length of f2; wherein f1 is positive or negative, f2 is positive, and f1 is smaller than f2.

2. The tunable narrow spectral width high power semiconductor laser system as claimed in claim 1, wherein further includes two semiconductor laser modules and two optical systems, which are symmetrically arranged and share the same transmission grating, while narrowing the spectral width of the two semiconductor laser modules and independently adjusting the wavelengths of the two semiconductor laser modules.

3. The tunable narrow spectral width high power semiconductor laser system as claimed in claim 1, wherein one of the first and second cylindrical lenses is placed on a translation stage to adjust the distance between the first and second cylindrical lenses to f1+f2 to narrow the spectral width of the laser spectrum.

4. The tunable narrow spectral width high power semiconductor laser system as claimed in claim 1, wherein further includes adjusting the tilt angle of the output coupler mirror and observing the output spectrum of the laser system, thereby suppressing the side mode and obtaining a narrow spectral width laser spectrum through optimal light feedback.

5. The tunable narrow spectral width high power semiconductor laser system as claimed in claim 1, wherein further includes adjusting the azimuth angle of the output coupler mirror and observing the output spectrum of the laser system to change the wavelength of the laser light.

6. A tunable narrow spectral width high power semiconductor laser system, comprising:
a semiconductor laser module, the semiconductor laser module has N laser diodes, each laser diodes is equipped with a fast-axis collimator, a slow-axis collimator and a reflective mirror at different height, so that N laser beams stacked along fast-axis of the diode laser on the output plane;
an optical system, composed of a first cylindrical lens, a second cylindrical lens, a half wave plate, a transmission grating and an output coupler mirror; the laser beam passes through the half wave plate to change the polarization direction, and passes through the transmission grating at an incident angle, rotating the half wave plate to change the polarization direction and adjusting the transmission grating to change the incident angle to obtain the maximum first-order diffraction efficiency of the transmitted light, the transmitted light passes through the first cylindrical lens and the second cylindrical lens in the optical system in sequence, condensed in the slow axis direction to a beam with a smaller cross-sectional area and a larger divergence angle, then the transmitted light is vertically incident on the output coupler mirror, and a light beam with R1 times incident power is reflected back to each laser diodes in the semiconductor laser module along the original path; and
the first cylindrical lens is close to the transmission grating and has a focal length of f1; the second cylindrical lens is close to the output coupler mirror and has a focal length of f2; wherein f1 is positive, f2 is positive or negative, and f1 is larger than f2.

7. The tunable narrow spectral width high power semiconductor laser system as claimed in claim 6, wherein further includes two semiconductor laser modules and two optical systems, which are symmetrically arranged and share the same transmission grating, while narrowing the spectral width of the two semiconductor laser modules and independently adjusting the wavelengths of the two semiconductor laser modules.

8. The tunable narrow spectral width high power semiconductor laser system as claimed in claim 6, wherein one of the first and second cylindrical lenses is placed on a translation stage to adjust the distance between the first and second cylindrical lenses to f1+f2 to narrow the spectral width of the laser spectrum.

9. The tunable narrow spectral width high power semiconductor laser system as claimed in claim 6, wherein further includes adjusting the tilt angle of the output coupler mirror and observing the output spectrum of the laser system, thereby suppressing the side mode and obtaining a narrow spectral width laser spectrum through optimal light feedback.

10. The tunable narrow spectral width high power semiconductor laser system as claimed in claim 6, wherein further includes adjusting the azimuth angle of the output coupler mirror and observing the output spectrum of the laser system to change the wavelength of the laser light.
